(19) United States
(12) Patent Application Publication
(10) Pub. No.: US 2026/0040868 A1
(43) Pub. Date: Feb. 5, 2026

(54) FILLER-APPLICATION APPARATUS

(71) Applicant: EBARA CORPORATION, Tokyo (JP)

(72) Inventors: Masayuki SATAKE, Tokyo (JP); Kazuhiro TAJIMA, Tokyo (JP)

(21) Appl. No.: 19/099,096

(22) PCT Filed: Jun. 29, 2023
(86) PCT No.: PCT/JP2023/024142

§ 371 Date: Jan. 28, 2025

(30) Foreign Application Priority Data
Aug. 5, 2022 (JP) 2022-125468

(51) Int. Cl. H01L 21/67; H01L 21/56

(52) U.S. Cl. CPC H01L 21/67126; H01L 21/56

(57) ABSTRACT

The present application relates to a filler-application apparatus for applying a filler to a gap formed between edge portions of a plurality of substrates that constitute a laminated substrate. The filler-application apparatus includes: a substrate holder configured to hold and rotate a laminated substrate manufactured by bonding a first substrate and a second substrate; an application device located away from the laminated wafer held by the substrate holder, and configured to inject a filler toward a gap formed between a peripheral portion of the first substrate and a peripheral portion of the second substrate; and a protector configured to prevent liquid splashes of the filler, which occur when the filler injected from the application device collides with the gap, from coming into contact with an upper surface and/or a lower surface of the laminated substrate.

### TECHNICAL FIELD

The present invention relates to a filler-application apparatus for applying a filler to a gap formed between edge portions of a plurality of substrates which constitute a laminated substrate.

### BACKGROUND ART

Recently, in order to achieve further higher density and functionality in semiconductor devices, development of three-dimensional packaging technology, in which a plurality of substrates are laminated and integrated three-dimensionally, has been advanced. In the three-dimensional packaging technology, a device surface of a first substrate on which integrated circuits and electrical wiring are formed is, for example, bonded to a device surface of a second substrate on which integrated circuits and electrical wiring are similarly formed. Further, after the first substrate has been bonded to the second substrate, the second substrate is thinned by a grinding apparatus. In this manner, integrated circuits can be laminated in a direction perpendicular to the device surfaces of the first and second substrates. In this specification, a form in which a plurality of substrates is bonded to each other may be referred to as a “laminated substrate”. Further, in this specification, a form in which a plurality of wafers, which are one example of the substrate, is bonded to each other may be referred to as a “laminated wafer”.

Generally, a circumferential surface of the substrate is polished in advance in a rounded shape in order to prevent cracking or chipping thereof. When the second substrate having such circumferential surface with the rounded shape is grinded, an acute edge is formed on the second substrate as a result of the grinding. This acute edge portion (which will be hereinafter referred to as a “knife-edge portion”) is constituted by the grinded back surface and the circumferential surface of the second substrate. Such knife-edge portion is likely to be chipped by a physical contact, and the laminated substrate itself may be broken during transportation of the laminated substrate. Further, insufficient bonding between the first substrate and second substrate may cause the second substrate to be cracked during grinding.

Thus, in order to prevent cracking and chipping of the knife-edge portion, a filler is applied to the edge portion in the laminated substrate before the second substrate is ground (see, for example, Patent Document 1). The filler is applied to a gap formed between an edge portion of the first substrate and an edge portion of the second substrate. The filler enables the knife-edge portion, formed after the second substrate is ground, to be supported, and thereby preventing cracking and chipping of the knife-edge portion.

### CITATION LIST

### Patent Literature

Patent document 1: Japanese laid-open patent publication No. 2022-38834

### SUMMARY OF INVENTION

### Technical Problem

In a filler-application module described in Patent Document 1, the filler is injected into the gap formed between adjacent substrates (hereinafter simply referred to as the “gap in the laminated substrate”) from an application module that is separated from the laminated substrate. At this time, the filler discharged from the application module may collide with the gap in the laminated substrate, and as a result, the filler may be scattered, contaminating an upper surface and/or a lower surface of the laminated substrate. More specifically, there is a risk that liquid splashes of the filler generated by the contact with the laminated substrate may adhere to the upper surface and/or the lower surface of the laminated substrate, contaminating these surfaces.

Contamination of the laminated substrate by liquid splashes of the filler may cause adverse effects on subsequent processing of the laminated substrate, resulting in a decrease in device yield.

It is therefore an object of the present invention to provide a filler-application apparatus capable of preventing an upper surface and/or a lower surface of a laminated substrate from being contaminated by liquid splashes of a filler.

### Solution to Problem

In one embodiment, there is provided a filler-application apparatus comprising: a substrate holder configured to hold and rotate a laminated substrate manufactured by bonding a first substrate and a second substrate; an application device located away from the laminated wafer held by the substrate holder, and configured to inject a filler toward a gap formed between a peripheral portion of the first substrate and a peripheral portion of the second substrate; and a protector configured to prevent liquid splashes of the filler, which are generated when the filler injected from the application device collides with the gap, from coming into contact with an upper surface and/or a lower surface of the laminated substrate.

In one embodiment, the protector is a plate with an opening that allows a bevel portion of the laminated substrate, which is rotated by the substrate holder, to pass through.

In one embodiment, the plate has an upper surface that is located between a tip and an end of the bevel portion of the laminated substrate when viewed in a radial direction of the laminated substrate.

In one embodiment, an edge of the opening in the plate is made of a material that allows contact with the laminated substrate, or is coated with that material.

In one embodiment, the plate is made of a material that can adsorb the filler, or is coated with that material.

In one embodiment, the protector has a suction nozzle that is arranged in proximity to a collision area of the laminated substrate with the filler.

In one embodiment, the protector is a dome configured to cover a collision area of the laminated substrate with the filler, and the dome has a through-hole that allows the filler, which has been injected from the application device, to pass through.

In one embodiment, the protector further has a dome configured to cover a part of the laminated substrate protruding from the opening in the plate, and the dome has a through-hole that allows the filler, which has been injected from the application device, to pass through.

In one embodiment, the dome is made of a material that can adsorb the filler, or is coated with that material.

In one embodiment, the dome has a plurality of suction holes extending from an inner surface to an outer surface of the dome, the protector includes a dome-suction mechanism configured to suction an internal space of the dome through the plurality of suction holes from an outer side of the dome, and the dome-suction mechanism includes at least one suction nozzle arranged in proximity to an outer surface of the dome.

In one embodiment, the dome has a plurality of non-penetrating holes formed in an inner surface of the dome.

In one embodiment, the application device is a dispenser configured to inject the filler as intermittent droplets into the gap in the laminated substrate.

### ADVANTAGEOUS EFFECTS OF INVENTION

According to the present invention, the protector prevents the liquid splashes of the filler from reaching to the laminated substrate, and as a result, the upper surface and the lower surface of the laminated substrate are prevented from being contaminated by the liquid splashes of the filler.

### BRIEF DESCRIPTION OF DRAWINGS

FIG. 1 is a front view showing a filler-application apparatus according to one embodiment;

FIG. 2 is a side view schematically showing the filler-application apparatus shown in FIG. 1

FIG. 3A is an enlarged cross-sectional view showing an example of a peripheral portion in a wafer;

FIG. 3B is an enlarged cross-sectional view showing another example of the peripheral portion in the wafer;

FIG. 4A is a schematic view showing an example of a laminated wafer in which two wafers are bonded to each other;

FIG. 4B is a schematic view showing the laminated wafer after a second wafer shown in FIG. 4A has been thinned;

FIG. 5 is a schematic view showing an application module according to one embodiment;

FIG. 6 is a plan view schematically showing a protector as shown in FIGS. 1 and 2;

FIG. 7A is a front view schematically showing the protector as shown in FIG. 6;

FIG. 7B is a view illustrating a tip and an end of the bevel portion of the laminated wafer;

FIG. 8 is a schematic view showing the protector according to another embodiment;

FIG. 9 is a side view schematically showing the protector according to still another embodiment;

FIG. 10 is a plan view schematically showing the protector shown in FIG. 9;

FIG. 11 is a side view schematically showing the protector according to still another embodiment;

FIG. 12 is a side view schematically showing the protector according to still another embodiment;

FIG. 13 is a side view schematically showing the protector according to still another embodiment;

FIG. 14 is a front view showing the filler-application apparatus according to another embodiment;

FIG. 15 is a front view showing the filler-application apparatus according to still another embodiment; and

FIG. 16 is a top view showing the filler-application apparatus according to still another embodiment.

### DESCRIPTION OF EMBODIMENTS

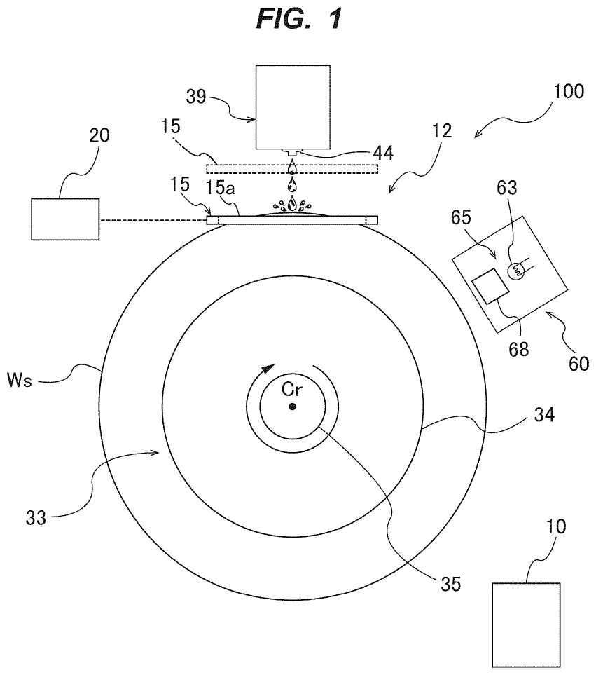

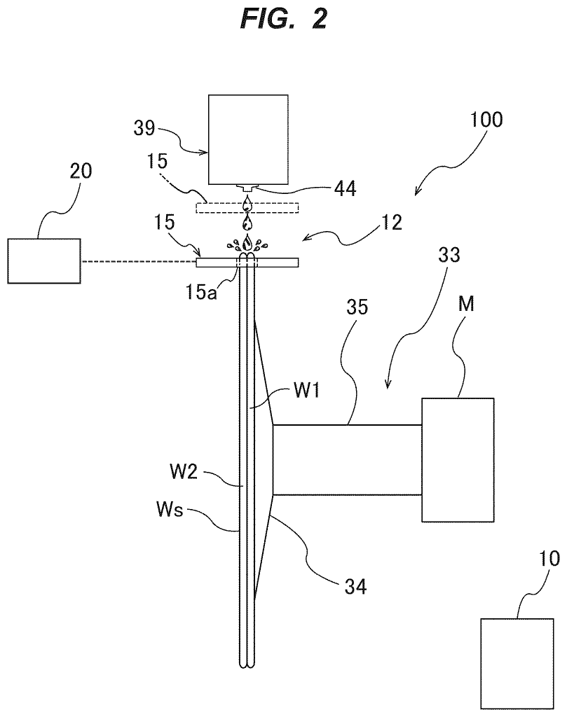

Embodiments will be described below with reference to the drawings. FIG. 1 is a front view showing a filler-application apparatus according to one embodiment, and FIG. 2 is a side view schematically showing the filler-application apparatus shown in FIG. 1. The filler-application apparatus 100 shown in FIGS. 1 and 2 is an apparatus for applying and curing a filler to protect a knife-edge portion formed in a peripheral portion of a second wafer when thinning a laminated wafer, which is an example of a laminated substrate, in which a first wafer is bonded to the second wafer.

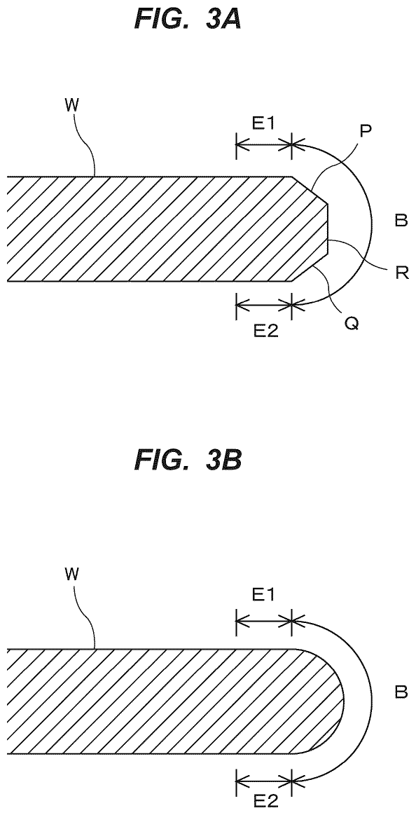

FIGS. 3A and 3B are enlarged cross-sectional views each showing a peripheral portion of a wafer which is an example of a substrate. More specifically, FIG. 3A is a cross sectional view of a wafer of a so-called straight type, and FIG. 3B is a cross sectional view of a wafer of a so-called round type. In a wafer W shown in FIG. 3A, a bevel portion is an outermost circumferential surface (indicated by symbol B) including an upper slope (or an upper bevel portion) P, a lower slope (or a lower bevel portion) Q, and a side portion (or an apex) R of the wafer W.

In a wafer W shown in FIG. 3B, a bevel portion is a portion (indicated by symbol B) constituting an outermost circumferential surface of the wafer W and having a curved cross section. A top edge portion E1 is a flat portion located radially inwardly of the bevel portion B and located radially outwardly of a region D where devices are formed. A bottom edge portion E2 is a flat portion located radially inwardly of the bevel portion B and located at an opposite side from the top edge portion E1. The top edge portion E1 and the bottom edge portion E2 may be collectively referred to as a near edge portion.

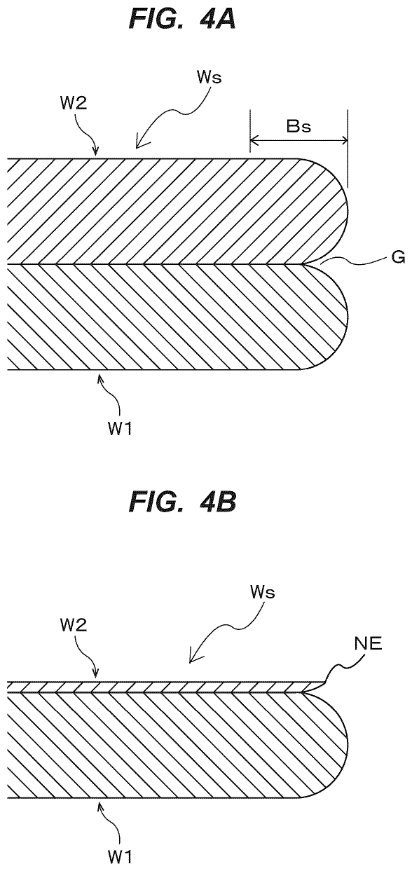

FIG. 4A is a schematic view showing an example of a laminated wafer in which two wafers are bonded to each other, and FIG. 4B is a schematic view showing the laminated wafer after the second wafer shown in FIG. 4A has been thinned. The laminated wafer Ws shown in FIG. 4A is manufactured by bonding a first wafer W1 and a second wafer W2 of the round type shown in FIG. 3B. A gap G is formed between peripheral portions of the first wafer W1 and the second wafer W2.

As shown in FIG. 4B, when the second wafer W2 is thinned, a knife-edge portion NE is formed in the peripheral portion of the second wafer W2. This knife-edge portion NE is likely to be chipped by physical contact, and may cause the laminated wafer Ws to be cracked or chipped during transportation of the laminated wafer Ws and during further processing of the laminated wafer Ws. Further, insufficient bonding between the first wafer W1 and the second wafer W2 may cause the second wafer W2 to be cracked or chipped during a grinding process of the second wafer W2 (i.e., a thinning process). Also in a case where the laminated wafer Ws is manufactured by bonding a first wafer W1 and a second wafer W2 of the square type shown in FIG. 3A, a knife-edge portion is formed in the peripheral portion of the second wafer W2 when the second wafer W2 is thinned. In the present specification, a portion of the laminated wafer Ws corresponding to the bevel portion B of the first wafer W1 and the bevel portion B of the second wafer W2 may be referred to as a “bevel portion Bs of the laminated wafer Ws”, or simply as a “bevel portion Bs”.

Therefore, the filler-application apparatus 100 is used to apply a filler to the gap G formed between the first wafer W1 and the second wafer W2 of the laminated wafer Ws, and then to cure this filler, thereby effectively protecting the knife-edge portion NE.

As shown in FIGS. 1 and 2, this filler-application apparatus 100 includes a rotary-holding mechanism (substrate holder) 33 in a center thereof, which vertically holds and rotates the laminated wafer Ws (see FIG. 4A) in which the plurality of wafers W1, W2 are laminated. FIGS. 1 and 2 illustrate a state in which the rotary-holding mechanism 33 holds the laminated wafer Ws, respectively. As shown in FIG. 2, when the laminated wafer Ws is held in a vertical state by the rotary-holding mechanism 33, an upper surface and a lower surface of the laminated wafer Ws are in virtual planes extending in a vertical direction perpendicular to the horizontal direction, respectively.

In the embodiment shown in FIGS. 1 and 2, the rotary-holding mechanism 33 has a dish-shaped holding stage 34 configured to hold a back surface of the laminated wafer Ws by use of a vacuum suction, a hollow shaft 35 coupled to a central portion of the holding stage 34, and a motor M for rotating the hollow shaft 35. The laminated wafer Ws is placed onto the holding stage 34 by hands of the substrate transfer mechanism (not shown) such that a center of the laminated wafer Ws is aligned with a central axis of the hollow shaft 35. The motor M is configured to rotate the holding stage 34 and the laminated substrate Ws in unison around a central axis Cr of the laminated substrate Ws in a direction indicated by an arrow in FIG. 25.

The filler-application apparatus 100 further includes an application module (application device) 39 configured to apply a filler F to the laminated wafer Ws, a curing module (curing device) 60 configured to cure the filler F applied by the application module 39, and a controller 10 configured to control operations of the filler-application apparatus in its entirety, including the rotary-holding mechanism 33, the application module 39, and the curing module 60.

The application module 39 is located outwardly in a radial direction of the laminated wafer Ws held by the holding stage 34, and is configured to apply the filler F to the gap G (see FIG. 4A) formed between a peripheral edge portion (edge portion E) of the first wafer W1 and a peripheral edge portion (edge portion E) of the second wafer W2 of the laminated wafer Ws. In this embodiment, the application module 39 is arranged above the laminated wafer Ws held by the holding stage 34 so as to face the gap G in the laminated wafer Ws.

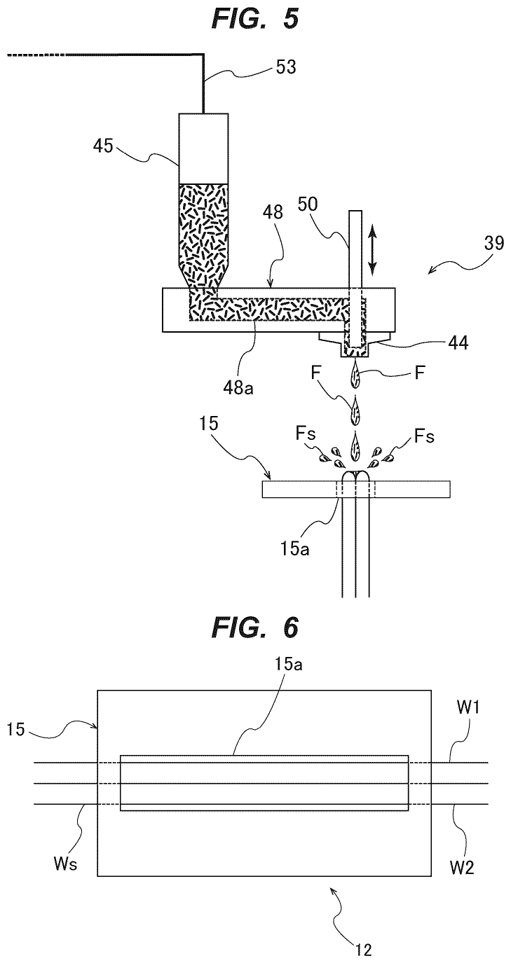

FIG. 5 is a schematic view showing an application module according to one embodiment. The application module 39 shown in FIG. 5 is configured as a dispenser having a discharge nozzle 44 for the filler F, which injects the filler F from the discharge nozzle 44 into the gap G in the laminated wafer Ws. Hereinafter, the application module 39 may be referred to as the “dispenser 39”. The dispenser 39 is a non-contact type application module, which is located away from the laminated wafer Ws.

The dispenser 39 shown in FIG. 5 includes a syringe 45 filled with the filler F, a support plate (support member) 48 which supports the syringe 45 and in which a filler flow channel 48a is formed to communicate with the discharge nozzle 44, and a rod 50 which can move back and forth within the support plate 48 so as to open and close the filler flow channel 48a of the support plate 48. The syringe 45 is coupled to a pressurized-fluid line 53 extending from a pressurized-fluid supply source which is not shown. A pressure of pressurized fluid (e.g., compressed air, pressurized nitrogen) supplied to the syringe 45 through the pressurized-fluid line 53 is applied to the filler F stored in the syringe 45.

In this embodiment, the syringe 45 is coupled to a connection port formed in an upper surface of the support plate 48, and the filler flow channel 48a of the support plate 48 is composed of a connection channel extending downward from the connection port between the syringe 45 and the support plate 48, a horizontal flow channel extending horizontally from the connection channel, and a discharge flow channel extending downward from the horizontal flow channel toward the dispenser 39. The rod 50 passes through the support plate 48 from the upper surface of the support plate 48 through the discharge flow channel 48a of the filler flow channel which extends downward, and extends to the discharge nozzle 44.

The dispenser 39 further includes an up-and-down movement mechanism (not shown) capable of moving the rod 50 up and down. The up-and-down movement mechanism causes the rod 50 to move up and down at high speed, so that droplets of the filler F are intermittently injected from the discharge nozzle 44 toward the gap G in the laminated wafer Ws. The droplets of the filler F injected from the discharge nozzle 44 fall toward the gap G, and as a result, the filler F can be applied to the gap G in the laminated wafer Ws. When the application of the filler F is completed, the up-and-down movement mechanism causes the rod 50 to be moved downward to close a discharge opening of the discharge nozzle 44 with a tip of the rod 50. This downward movement of the rod 50 prevents the filler F from leaking out from the discharge nozzle 44 even though a state where the pressure of the pressurized-fluid is applied to the filler F in the syringe 45 is maintained.

As long as the dispenser 39 can apply the filler F to the gap G in the laminated wafer Ws, the type and configuration of the dispenser 39 are not limited to the embodiment shown in FIG. 5. For example, the dispenser 39 may supply the filler F to the gap G in the laminated substrate Ws in a continuous flowing of the filler F.

The filler F applied to the gap G in the laminated wafer Ws by the dispenser 39 is cured by the curing module 60, which is arranged downstream of a rotational direction of the laminated wafer Ws rotated by the rotary-holding mechanism 33. The curing module 60 is a device for curing the filler F supplied to the laminated wafer Ws by the dispenser 39. In this embodiment, the filler F is a filler having thermosetting properties. Examples of such filler F may be a thermosetting resin.

The curing module 60 shown in FIGS. 1 and 2 is configured as a light heating module having a lamp heater 65. The lamp heater 65 includes a lamp 63 and optical components 68 for directing heat (radiant heat) from the lamp 63 to the filler F applied to the gap G in the laminated wafer Ws. Although not shown in the drawings, the optical components 68 constitute, for example, mirrors and/or lenses.

The type and configuration of the curing module 60 are also freely selected as long as the filler F applied to the gap G in the laminated wafer Ws can be cured. For example, the curing module 60 may be a heat gun for blowing hot air into the gap G in the laminated wafer Ws.

The type of filler F is also freely selected as long as the filler F can be applied to the gap G in the laminated wafer Ws and can be cured in a short time. For example, the filler F may be a light-curing resin.

In the filler-application apparatus 100 configured in this manner, first, the laminated wafer Ws is held in a vertical state by vacuum suction in the holding stage 34 of the rotary-holding mechanism 33. Next, the laminated wafer Ws is rotated together with the holding stage 34. Next, the dispenser 39 causes the filler F to be applied to the gap G in the laminated wafer Ws, and further, the curing module 60 causes the filler F applied to the gap G to be cured. The application process and the curing process of the filler F are performed continuously in the same processing chamber. Therefore, the wafer processing (substrate processing) to prevent the laminated wafer Ws from being cracked or chipped can be performed in a remarkably short time.

When the filler F is injected from the discharge nozzle 44 of the dispenser 39 toward the gap G in the laminated wafer Ws, there is a risk that the filler F collides with the gap G in the laminated wafer Ws, causing liquid splashes Fs of the filler F to occur. If the liquid splashes Fs of the filler F occur and an upper surface and/or a lower surface of the laminated wafer Ws are contaminated with the filler F, the subsequent processing of the laminated wafer Ws may be adversely affected, and as a result, the yield of the device may be decreased. Accordingly, the filler-application apparatus 100 according to this embodiment includes a protector 12 for preventing the liquid splashes of the filler F from reaching (i.e., adhering to) to the upper and/or lower surfaces of the laminated wafer Ws, and a moving mechanism 20 (see FIG. 1) for moving the protector 12 (or components of the protector 12) to be brought close to and away from the laminated wafer Ws held to the holding stage 34 of the rotary-holding mechanism 33.

The moving mechanism 20 enables the protector 12 (or components of the protector 12) to be moved between a protect position, where the protector 12 (or the components of the protector 12) prevents the liquid splashes of the filler F, and a standby position (see the dotted line in FIG. 1), where the protector 12 (or the components of the protector 12) is farther away from the laminated wafer Ws than the protect position. The standby position for the protector 12 is set to a position where operations of other devices, such as transfer of laminated wafer Ws, are not disturbed. The type and configuration of the moving mechanism 20 is freely selected as long as the moving mechanism 20 enables the protector 12 (or the components of the protector 12) to be moved between the protector position and the standby position. For example, the moving mechanism 20 may be a piston-cylinder mechanism having a piston which is coupled to the protector 12 (or the component of the protector 12), or may be a combination of a ball screw and a motor (e.g., a stepping motor).

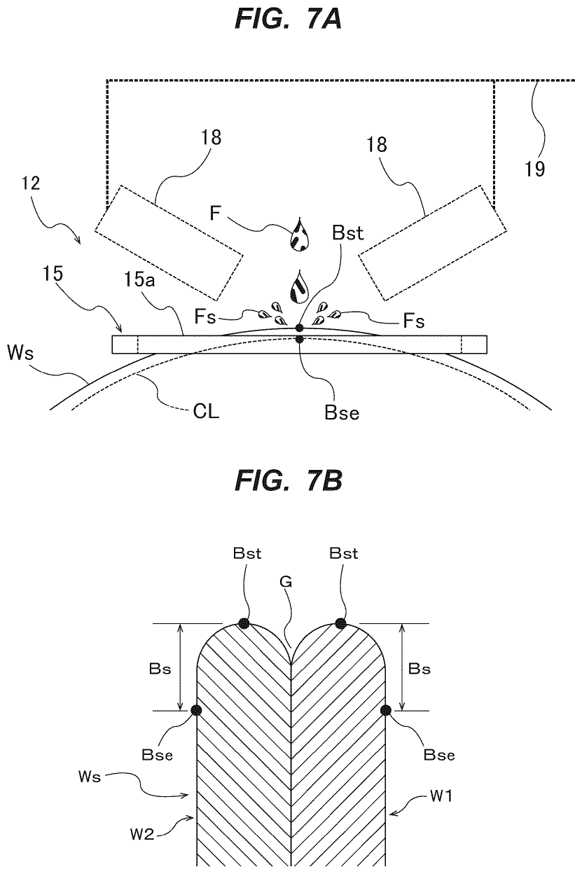

FIG. 6 is a plan view schematically showing the protector as shown in FIGS. 1 and 2. FIG. 7A is a front view schematically showing the protector as shown in FIG. 6, and FIG. 7B is a view illustrating a tip and an end of the bevel portion of the laminated wafer. FIG. 7A illustrates the protector 12 moved to the protect position.

The protector 12 shown in FIGS. 6 and 7A is a plate 15 with an opening 15a. As shown in FIG. 7A, the opening 15a has a size that allows at least a peripheral portion (e.g., see bevel portion Bs in FIG. 4A) of the laminated substrate Ws held by the holding stage 34 of the rotary-holding mechanism 33 to pass through, and when the plate 15 is moved to the protect position, a part of the peripheral portion of the laminated wafer Ws protrudes from an upper surface of the plate 15 through the opening 15a. The liquid splashes Fs of the filler F is caught by the upper surface of the plate 15, thereby preventing the liquid splashes Fs of the filler F from contaminating the upper surface and/or the lower surface of the laminated wafer Ws.

The upper surface of the plate 15 which has been moved to the protect position is located at least below a top portion of the laminated wafer Ws held by the rotary-holding mechanism 33. In order to effectively prevent the liquid splashes Fs of the filler F from reaching the upper surface and/or the lower surface of the laminated wafer Ws, edges of the opening 15a of the plate 15 are preferably as close as possible to the laminated wafer Ws. Accordingly, as shown in FIG. 7A, the upper surface of the plate 15 moved to the protect position is preferably located between a tip Bst and an end Bse of the bevel portion Bs in the laminated wafer Ws. As shown in FIG. 7B, the tip Bst of the bevel portion Bs of the laminated wafer Ws is located in the outermost circumference of the laminated wafer Ws, and corresponds to a top of the wafer W1 and a top of the wafer W2 of the laminated wafer Ws held by the holding stage 34 of the rotary-holding mechanism 33. Further, as shown in FIG. 7B, the end Bse of the bevel portion Bs of the laminated wafer Ws in either of the wafer W1 or the wafer W2 is located radially inside the tip Bst of the bevel portion Bs of the laminated wafer Ws on a circular connecting line CL (see FIG. 7A) between the bevel portion Bs and the device surface.

In one embodiment, the edges of the opening 15a of the plate 15 may be made of a flexible material that allows contact with the upper surface and the lower surface of the laminated wafer Ws, or may be coated with this type of flexible material. In these cases, the application and the curing of the filler F may be performed with the edges of the opening 15a of the plate 15 in contact with the laminated wafer Ws. Examples of this type of flexible material may include (high-molecular) resin materials, such as sponge.

Further, the plate 15 may be made of a material that can adsorb the filler F, or may be coated with this type of material. Examples of material that can adsorb the filler F may include (high-molecular) resin material such as sponge, and porous resin material. Further, the plate 15 may be made of a material that can contact the upper surface and the lower surface of the laminated wafer Ws and that can adsorb the filler F, or may be coated with this type of material. In addition, the edges of the openings 15a of the plate 15 may be made of or coated with a material that can contact the upper surface and the lower surface of the laminated wafer Ws and that can adsorb the filler F.

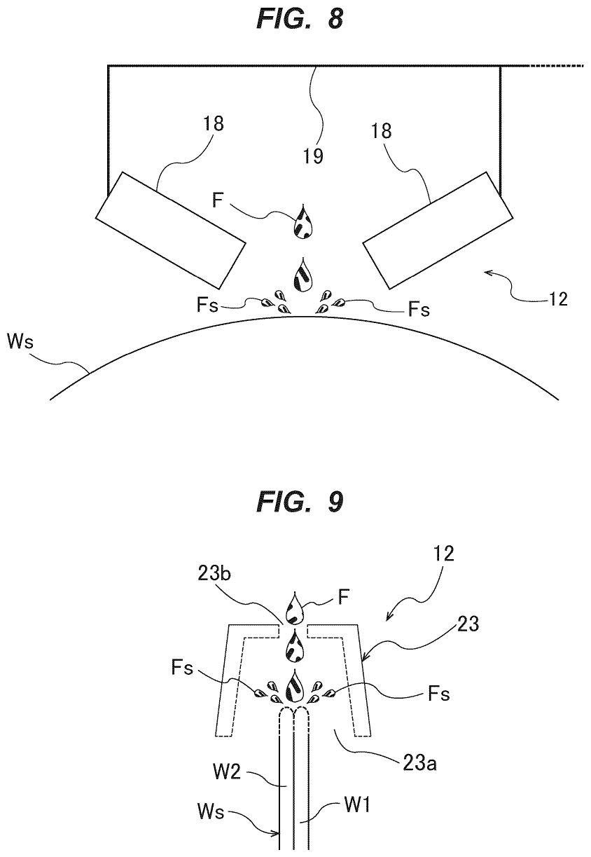

FIG. 8 is a schematic view showing the protector according to another embodiment. The protector 12 shown in FIG. 8 is a suction mechanism, which has at least one (two in the example shown) of suction nozzles 18 arranged in proximity to a collision area of the laminated wafer Ws with the filler F, and a vacuum line 19 extending from each of the suction nozzles 18 to a vacuum source (e.g., a suction pump) not shown. In one embodiment, a flow-rate regulator, such as a flow-rate control valve, may be provided in the vacuum line 19, or a pressure gauge may be disposed in the vacuum line 19.

Although not shown in the drawings, in this embodiment also, a moving mechanism 20 is provided to move the suction nozzles 18 of the protector 12 between the protect position where the suction nozzles 18 prevent the liquid splashes of the filler F, and the standby position where the suction nozzles 18 are farther away from the laminated wafer Ws than the protect position.

According to the suction mechanism of the protector 12 in this embodiment, the suction nozzles 18 cause liquid droplets of the filler F, which are generated when the filler F collides with the gap G in the laminated wafer Ws, to be sucked up, so that the liquid splashes of the filler F are prevented from contaminating the upper surface and/or the lower surface of the laminated wafer Ws.

As shown by imaginary lines (dotted lines) in FIG. 7, the protector 12 may include, in addition to the plate 15, at least one of suction nozzles 18 arranged in proximity to the opening 15a of the plate 15, which is the collision area of the laminated wafer Ws with the filler F and the vacuum line 19 extending from each of the suction nozzles 18 to a vacuum source (e.g., a suction pump) not shown. In this case, the moving mechanism 20 causes the plate 15 and the suction nozzles 18 to be moved between the protect position and the standby position.

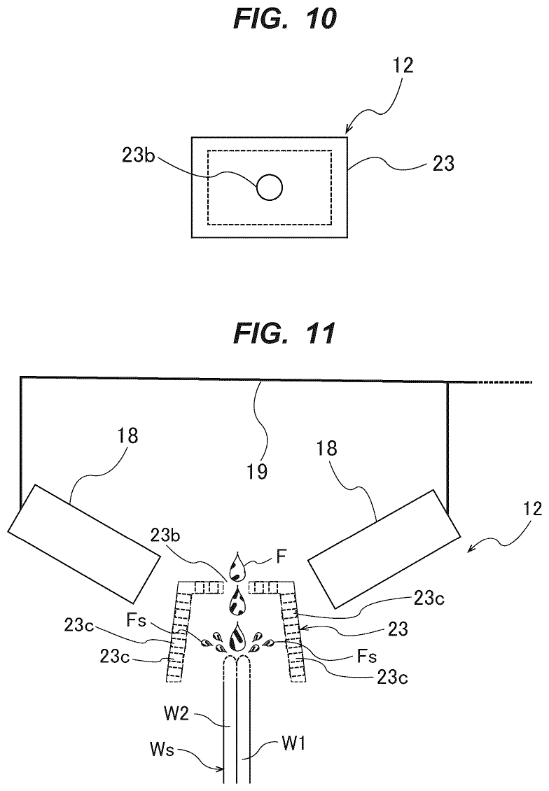

FIG. 9 is a side view schematically showing the protector according to still another embodiment, and FIG. 10 is a plan view schematically showing the protector shown in FIG. 9. The protector 12 shown in FIGS. 9 and 10 includes a dome 23 for covering the collision area of the laminated wafer Ws with the filler F. The dome 23 has an opening 23a facing the laminated wafer Ws held by the holding stage 34 of the rotary-holding mechanism 33. When the moving mechanism 20 causes the dome 23 to be moved to the protect position, the peripheral portion of the laminated wafer Ws enters an internal space of the dome 23 through the opening 23a.

The dome 23 has a through-hole 23b at a top thereof, which allows the filler F injected from the dispenser 39 to pass through. Further, an inner wall of the dome 23 is in proximity to the collision area of the laminated wafer Ws with the filler F.

The dome 23 may be made of a material that can adsorb the filler F, or may be coated with this type of material. In one embodiment, only the inner wall of the dome 23 may be coated with the material that can adsorb the filler F. With this configuration, the droplets of the filler F, which are generated when the filler F collides with the gap G in the laminated wafer Ws, are adsorbed to the inner wall of the dome 23, thereby preventing the liquid splashes of the filler F from contaminating the upper surface and/or the lower surface of the laminated wafer Ws. In this embodiment also, examples of the material that can adsorb the filler F may include (high-molecular) resin material, such as sponge, and porous resin material.

In this embodiment, the dome 23, which has adsorbed the filler F, is periodically replaced. A replacement cycle for the dome 23 is determined, for example, by experiments or simulations performed in advance. The replacement cycle for the dome 23 may be stored in advance in the controller 10 as the number of laminated wafers Ws processed. In this case, every time the dome 23 is replaced, the controller 10 resets the number of processed wafers and starts a new count of the number of processed wafers. The controller 10 may be configured to issue a replacement alarm for the dome 23 when the number of processed wafers reaches the replacement cycle.

Although not shown in the drawings, in this embodiment also, the moving mechanism 20 is provided to move the dome 23 of the protector 12 between the protect position where the dome 23 prevents the liquid splashes of the filler F and the standby position where the dome 23 is farther away from the laminated wafer Ws than the protect position.

FIG. 11 is a side view schematically showing the protector according to still another embodiment. Configurations of this embodiment, which will not be particularly described, are the same as the embodiment described with reference to FIGS. 9 and 10, and redundant descriptions thereof will be omitted.

The dome 23 of the protector 12 shown in FIG. 11 is made of a porous material, such as punched metal. In other words, the dome 23 has a plurality of suction holes 23c extending from an inner surface to an outer surface thereof. Furthermore, the protector 12 has at least one of suction nozzles 18 arranged in proximity to the outer surface of the dome 23 and a vacuum line 19 extending from each of the suction nozzles 18 to a vacuum source (e.g., a suction pump) not shown. With this configuration, the droplets Fs of the filler Fare sucked into the suction nozzles 18 from the internal space of the dome 23 through the plurality of suction holes 23c of the dome 23, and as a result, the liquid splashes Fs of the filler F is prevented from contaminating the upper surface and/or the lower surface of the laminated wafer Ws.

In this embodiment, the dome 23, in particular, the suction holes 23c of the dome 23, may be contaminated by the filler F, and thus there is a risk that the suction holes 23c of the dome 23 may become blocked by the filler F. For this reason, the dome 23 is periodically cleaned. The cleaning cycle for the dome 23 is determined, for example, by experiments or simulations performed in advance. The cleaning cycle for the dome 23 may be stored in advance in the controller 10, for example, as the number of laminated wafers Ws processed. In this case, every time the dome 23 is cleaned, the controller 10 resets the number of processed wafers and starts a new count of the number of processed wafers. The controller 10 may be configured to issue an alarm to prompt the replacement of the dome 23 when the number of processed wafers reaches the replacement cycle.

In one embodiment, a pressure sensor (e.g., vacuum gauge) may be disposed in the vacuum line 19, and the dome 23 may be cleaned when a measurement value of the pressure sensor exceeds a predetermined threshold value. In this case, the pressure sensor is coupled to the controller 10, and the controller 10 monitors a pressure of the vacuum line 19. Further, the controller 10 stores the predetermined threshold value in advance, and is configured to issue an alarm to prompt cleaning of the dome 23 when the measurement value of the pressure in the vacuum line 19 exceeds the predetermined threshold value.

Although not shown in the drawings, in this embodiment also, the moving mechanism 20 is provided to move the dome 23 and the suction nozzles 18 of the protector 12 between the protect position where the dome 23 and the suction nozzles 18 prevent the liquid splashes of the filler F, and the standby position where the dome 23 and the suction nozzles 18 is farther away from the laminated wafer Ws than the protect position.

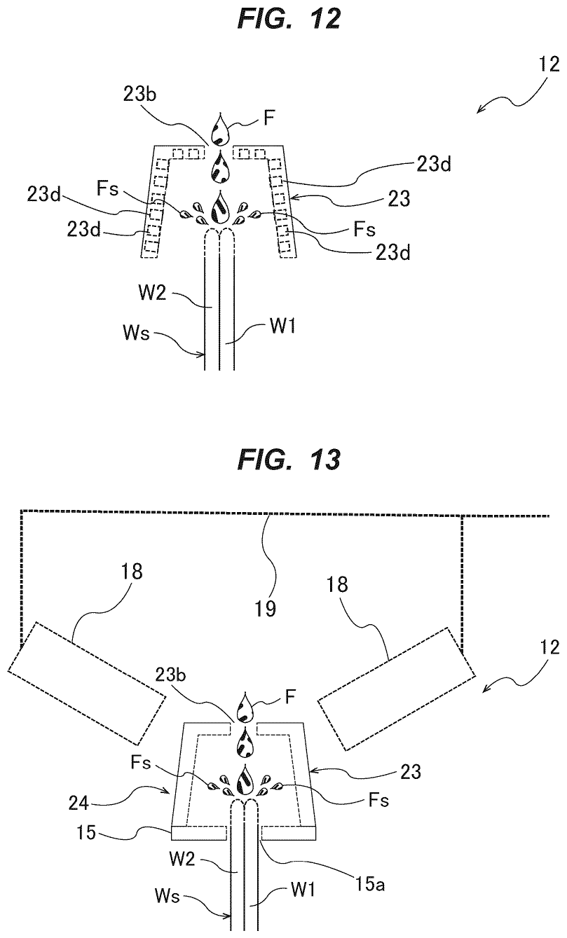

FIG. 12 is a side view schematically showing the protector according to still another embodiment. The protector 12 shown in FIG. 12 includes the dome 23 for covering the collision area of the laminated wafer Ws with the filler F, and the dome 23 has a plurality of non-penetrating holes 23d. Each of the non-penetrating holes 23d is a recess formed in the inner wall (i.e., inner surface) of the dome 23.

In this embodiment also, the dome 23 is made of the material that can adsorb the filler F, or is coated with this type of material. In one embodiment, only the inner wall of the dome 23 may be coated with the material that can adsorb the filler F. With such configuration, the droplets of the filler F, which are generated when the filler F collides with the gap G in the laminated wafer Ws, are deposited in the inner surface of the dome 23, in particular, in the non-penetrating hole 23d, and thus effectively adsorbed in the inner surface of the dome 23. As a result, the liquid splashes of the filler F is prevented from contaminating the upper surface and/or the lower surface of the laminated wafer Ws. In this embodiment also, examples of material that can adsorb the filler F may include (high-molecular) resin material, such as sponge, and porous resin material.

In this embodiment also, the moving mechanism 20 is provided to move the dome 23 and the suction nozzles 18 of the protector 12 between the protect position where the dome 23 and the suction nozzles 18 prevent the liquid splashes of the filler F and the standby position where the dome 23 and the suction nozzles 18 are farther away from the laminated wafer Ws than the protect position. Further, in this embodiment also, the dome 23 is periodically cleaned. The cleaning cycle of the dome 23 is determined, for example, by experiments or simulations performed in advance. For example, the cleaning cycle for the dome 23 may be stored in advance in the controller 10 as the number of laminated wafers Ws processed. In this case, every time the dome 23 is cleaned, the controller 10 resets the number of processed wafers and starts a new count of the processed wafers. The controller 10 may be configured to issue an alarm to prompt the replacement of the dome 23 when the number of processed wafers reaches the replacement cycle.

FIG. 13 is a side view showing the protector according to still another embodiment. The protector 12 shown in FIG. 13 has a combination of the dome 23 and the plate 15 which are described above. Configurations of this embodiment, which will not be particularly described, are the same as the embodiments described above, and redundant descriptions thereof will be omitted.

In the embodiment shown in FIG. 13, the opening 23a of the dome 23 shown in FIGS. 9 and 10 is closed by the plate 15. The dome 23 may be integrally formed with the plate body 15, or the dome 23 formed as a separate body may be attached to the plate body 15. Hereinafter, the combination of the dome 23 and the plate body 15 may be referred to as a “bottomed dome 24”.

When the bottomed dome 24 is moved to the protect position, the peripheral portion of the laminated wafer Ws enters an internal space of the bottomed dome 24 through the opening 15a of the plate 15. The internal space of the bottomed dome 24 is a space partitioned by the dome 23 and the plate 15. The dome 23 is made of the material that can adsorb the filler F or is coated with this type of material. Alternatively, the dome 23 may be made of a porous material, such as punched metal. When the dome 23 is made of a porous material, the filler-application apparatus 100 is provided with a dome-suction mechanism. In this embodiment, the dome-suction mechanism is composed of at least one of suction nozzles 18 arranged proximal to the outer surface of the dome 23, and the vacuum line 19 extending from the vacuum source (e.g., suction pump) not shown to each of the suction nozzles 18.

Although not shown in the drawings, in this embodiment also, the moving mechanism 20 is provided to move the bottomed dome 24 (and suction nozzles 18) of the protector 12 between the protect position where the bottomed dome 24 (and suction nozzles 18) prevents the liquid splashes of the filler F, and the standby position where is farther away from the laminated wafer Ws than the protect position.

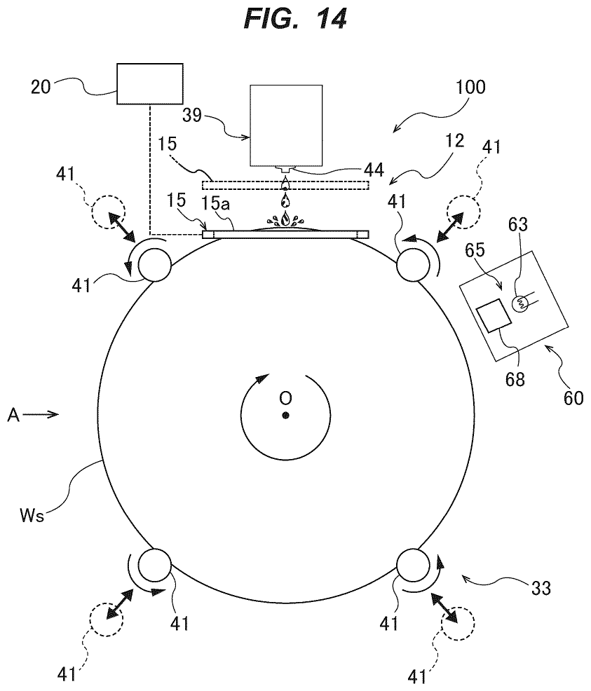

FIG. 14 is a front view showing the filler-application apparatus according to another embodiment. Configurations of this embodiment, which will not be particularly described, are the same as the embodiments described above, and redundant descriptions thereof will be omitted. This embodiment is different from the embodiments described above only in the configuration of the rotary-holding mechanism (substrate holder) 33.

Therefore, the protector 12 shown in FIG. 14 corresponds to the plate 15 described with reference to FIGS. 1 and 2, but the configuration of the protector 12 is not limited to this example. The protector 12 may have the configuration with the plate 15 and the suction nozzles 18 as described with reference to FIG. 7, the configuration with the suction nozzles 18 as described with reference to FIG. 8, the configuration with the dome 23 as described with reference to FIGS. 9 to 12, or the configuration with the bottomed dome 24 as described with reference to FIG. 13.

The rotary-holding mechanism 33 in this embodiment has three or more (four in this embodiment) rollers 41 that can be in contact with the peripheral portion of the laminated substrate Ws, a roller rotation mechanism (not shown) configured to rotate each of the rollers 41 around an axis center thereof, and a roller movement mechanism (not shown) configured to move the rollers 41, respectively. In this embodiment, the rotary-holding mechanism 33 has the four rollers 381, but the rotary-holding mechanism 303 may have three rollers 381, or five or more rollers 381.

The four rollers 41 are arranged around a reference center point O of the rotary-holding mechanism 33. The rollers 41 are configured so as to contact the peripheral portion of the laminated substrate Ws to hold the laminated substrate Ws vertically. More specifically, the laminated substrate Ws is held in the vertical state by the roller 41 of the rotary-holding mechanism 33.

The roller rotation mechanism is coupled to the four rollers 41, and is configured to rotate the four rollers 41 in the same direction and at the same speed. Configuration of the roller rotation mechanism is freely selected as long as the roller rotation mechanism can rotate three or more rollers 41 in the same direction and at the same speed, and thus any known rotation mechanism can be used as the roller rotation mechanism. Examples of the roller rotation mechanism may include a combination of motor, pulley (and/or gear), and rotation belt.

The roller movement mechanism is coupled to the four rollers 41, and is configured to move each of the rollers 41 in directions approaching toward and away from the reference center point O of the rotary-holding mechanism 33. The roller movement mechanism enables the four rollers 41 to be moved between a holding position (see solid line in FIG. 14), where the peripheral portion of the laminated substrate Ws is held by the rollers 41, and a release position (see dotted line in FIG. 14), where the laminated substrate Ws is released from the rollers 41. Configuration of the roller movement mechanism is freely selected as long as the four rollers 41 can be moved between the holding position and the release position, and thus any known movement mechanism can be used as the roller movement mechanism. Examples of the roller movement mechanism may include a piston-cylinder mechanism, and a combination of ball screw and motor (i.e., stepping motor).

The roller rotation mechanism and the roller movement mechanism of the rotary-holding mechanism 33 are electrically coupled to the controller 10, and operations of the roller rotation mechanism and the roller movement mechanism of the rotary-holding mechanism 33 are controlled by the controller 10.

The laminated substrate Ws is transferred by a transfer device not shown, to a position where the axis center of the laminated substrate Ws is aligned with the reference center point O of the rotary-holding mechanism 33. At this time, the rollers 41 are in the release position, and the protector 12 is in the standby position (see the dotted line in FIG. 14). Next, the roller movement mechanism causes the four rollers 41 to be moved to the holding position, so that the peripheral portion of the laminated substrate Ws is held by the four rollers 41. This operation causes the laminated substrate Ws to be held in the vertical state by the four rollers 41. When the four rollers 41 moved to the holding position are rotated by the roller rotation mechanism, the laminated substrate Ws is rotated around the axis center thereof.

When the four rollers 41 in the holding position are moved to the release position by the roller movement mechanism, the four rollers 41 are separated from the peripheral portion of the laminated substrate Ws, so that the laminated substrate Ws can be released from the four rollers 41. The released laminated substrate Ws is transferred from the rotary-holding mechanism 33 by the transfer device not shown.

The application process of the filler F by the dispenser 39 and the curing process of the filler F by the curing module 60 are performed while rotating the laminated substrate Ws, which is held vertically by the rotary-holding mechanism 33. While the dispenser 39 is applying the filler F, the protector 12 is moved to the protect position, thereby preventing the liquid splashes of the filler F from contaminating the upper surface and/or the lower surface of the laminated wafer Ws.

In one embodiment, the roller rotation mechanism may be configured to rotate only some of the rollers 41. For example, the roller rotation mechanism may be coupled to two of the four rollers 41, and be configured to rotate those two rollers in the same direction and at the same speed. In this case, the other two rollers 41 are configured to rotate freely. When two of the rollers 41 coupled to the roller rotation mechanism are rotated with the four rollers 41 in the hold position, the other two rollers 41 rotate through the laminated substrate Ws in accordance with the rotation of rollers 41 coupled to the roller rotation mechanism.

In one embodiment, the roller movement mechanism may be configured to move only some of the rollers 41. For example, the roller movement mechanism may be coupled to two of the four rollers 41, and be configured to move those two rollers 41 between the hold position and the release position. In this case, the other two rollers 41 are fixed in advance in the hold position. The laminated substrate Ws is transferred by the transfer device to a position where the peripheral portion of the laminated substrate Ws contacts the two fixed rollers 41. The roller movement mechanism moves the two rollers 41 coupled to the roller movement mechanism to the hold position, so that the laminated substrate Ws can be held in the vertical state. When the two rollers 41 coupled to the roller movement mechanism are moved by the roller movement mechanism to the release position, the laminated substrates Ws can be released.

In the embodiments described above, the rotary-holding mechanism 33 is configured to hold the laminated substrate Ws vertically. More specifically, the laminated substrate Ws is held in the vertical state by the rotary-holding mechanism 33. However, as long as the filler F can be applied to the gap G, the method of holding the laminated substrate Ws is not limited to the embodiments described above. For example, the filler-application apparatus 100 may have a rotary-holding mechanism 33 configured to hold the laminated substrates Ws horizontally. In this case, the laminated wafer Ws is held by the rotary-holding mechanism 33 in a horizontal state. When the laminated substrate Ws is held in the horizontal state, the upper surface and the lower surface of the laminated substrate Ws are in virtual planes, respectively, extending in a horizontal direction.

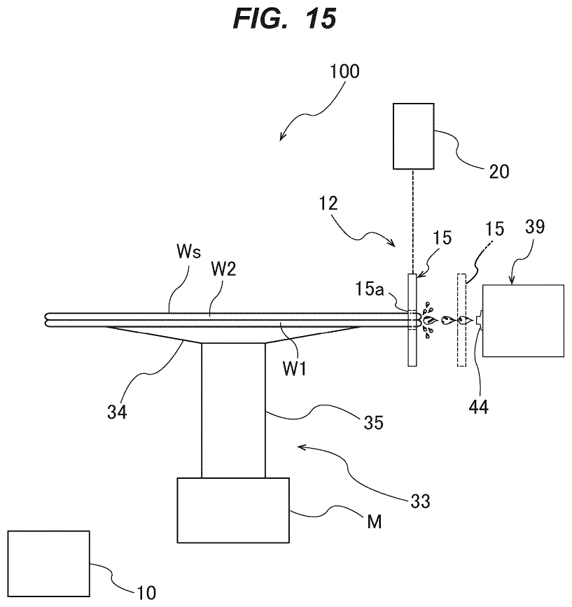

FIG. 15 is a front view showing the filler-application apparatus according to still another embodiment. The rotary-holding mechanism 33 of the filler-application apparatus 100 shown in FIG. 15 is different from the rotary-holding mechanism 33 of the filler-application apparatus 100 shown in FIGS. 1 and 2 in that the upper surface of the holding stage 34 is in a virtual plane extending in the horizontal direction such that the holding stage 34 causes the laminated wafer Ws to be held horizontally and to be rotated. In this embodiment also, the hollow shaft 35 is coupled to the central portion of the holding stage 34, and the rotary-holding mechanism 33 includes the motor M for rotating this hollow shaft 35.

The dispenser 39 and the curing module 60 are located radially outside the laminated wafer Ws, which is held horizontally by the rotary-holding mechanism 33. The filler F is injected horizontally from the dispenser 39, and applied to the gap G in the rotating laminated wafer Ws.

In this embodiment also, when the filler F injected horizontally from the dispenser 39 collides with the gap G in the laminated wafer Ws, the liquid splashes of the filler F occurs, and thus there is a risk that the upper surface and/or the lower surface of the laminated wafer Ws may be contaminated by the liquid splashes. Therefore, in this embodiment also, the filler-application apparatus 100 is provided with the protector 12.

The protector in this embodiment is the plate 15 described with reference to FIGS. 1 and 2, but is different from the embodiment described with reference to FIGS. 1 and 2 in that the moving mechanism 20 causes the plate 15 to be moved horizontally. Configuration of the protector 12 is not limited to this example. The protector 12 may have the configuration with the plate 15 and the suction nozzles 18 as described with reference to FIG. 7, the configuration with the suction nozzles 18 as described with reference to FIG. 8, the configuration with the dome 23 as described with reference to FIGS. 9 to 12, or the configuration with the bottomed dome 24 as described with reference to FIG. 13. In these cases, the moving mechanism 20 causes the plate 15, the suction nozzles 18, the dome 23, or the bottomed dome 24 to be moved horizontally.

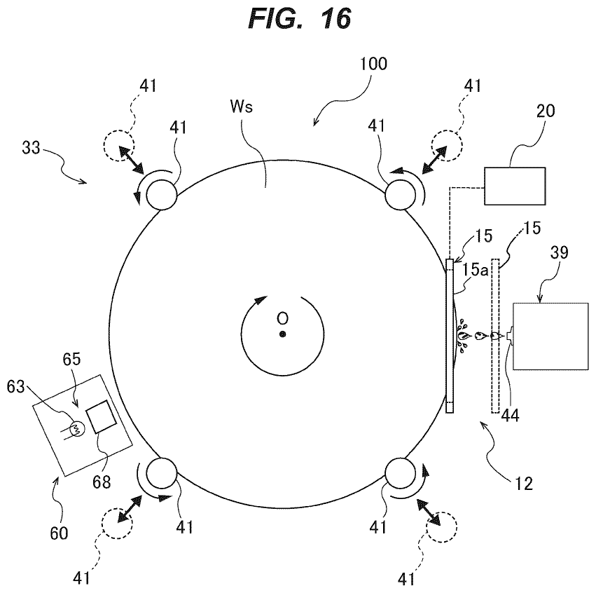

FIG. 16 is a top view showing the filler-application apparatus according to still another embodiment. The rotary-holding mechanism 33 of the filler-application apparatus 100 shown in FIG. 16 is different from the filler-application apparatus shown in FIG. 15 in that, instead of the holding stage 34, the hollow shaft 35, and the motor M, the rotary-holding mechanism 33 includes three or more (four in this embodiment) rollers 41 that can be in contact with the peripheral portion of the laminated substrate Ws, a roller rotation mechanism (not shown) configured to rotate each of the rollers 41 around an axis center thereof, and a roller movement mechanism (not shown) configured to move the rollers 41, respectively.

Configuration of three or more rollers 41 is the same as the embodiment described with reference to FIG. 14, except that the laminated wafer Ws is held horizontally. Further, the roller rotation mechanism is the same as the embodiment described with reference to FIG. 14, except that the laminated wafer Ws held horizontally by three or more rollers 41 is rotated. Moreover, the roller movement mechanism is also the same as the embodiment described with reference to FIG. 14, except that this mechanism causes three or more rollers 41 to be moved between a holding position (see the solid line in FIG. 16) where the peripheral edge of the laminated wafer Ws is held horizontally by the rollers 41 and a release position (see the dotted line in FIG. 16) where the laminated wafer Ws is released from the rollers 41.

In this embodiment also, when the filler F injected horizontally from the dispenser 39 collides with the gap G in the laminated wafer Ws, the liquid splashes of the filler F occurs, and thus there is a risk that the upper surface and/or the lower surface of the laminated wafer Ws may be contaminated by the liquid splashes. Therefore, in this embodiment also, the filler-application apparatus 100 is provided with the protector 12.

The protector 12 in this embodiment is the plate 15 described with reference to FIGS. 1 and 2, but is different from the embodiment described with reference to FIGS. 1 and 2 in that the moving mechanism 20 causes the plate 15 to be moved horizontally. Configuration of the protector 12 is not limited to this example. The protector 12 may have the configuration with the plate 15 and the suction nozzles 18 as described with reference to FIG. 7, the configuration with the suction nozzles 18 as described with reference to FIG. 8, the configuration with the dome 23 as described with reference to FIGS. 9 to 12, or the configuration with the bottomed dome 24 as described with reference to FIG. 13. In these cases, the moving mechanism 20 causes the plate 15, the suction nozzles 18, the dome 23, or the bottomed dome 24 to be moved horizontally.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a filler-application apparatus for applying a filler to a gap formed between edge portions of a plurality of substrates that constitute a laminated substrate.

### REFERENCE SIGNS LIST

10 controller
12 protector
15 plate
15a opening
18 suction nozzle
19 vacuum line
20 moving mechanism
23 dome
23a opening
23b through-hole
23c suction hole
23d non-penetrating hole
24 bottomed dome
33 rotary-holding mechanism (substrate holder)
34 holding stage
35 hollow shaft
39 application module (application device)
44 discharge nozzle
45 syringe
48 support plate (support member)
50 rod
53 pressurized-fluid line
60 curing module (curing device)
63 lamp
65 lamp heater
68 optical component
100 filler-application apparatus
F filler
Fs liquid splash
G gap
M motor
W1 first substrate (first wafer)
W2 second substrate (second wafer)
Ws laminated substrate (laminated wafer)

What is claimed is:

1. A filler-application apparatus comprising:
a substrate holder configured to hold and rotate a laminated substrate manufactured by bonding a first substrate and a second substrate;
an application device located away from the laminated wafer held by the substrate holder, and configured to inject a filler toward a gap formed between a peripheral portion of the first substrate and a peripheral portion of the second substrate; and
a protector configured to prevent liquid splashes of the filler, which are generated when the filler injected from the application device collides with the gap, from coming into contact with an upper surface and/or a lower surface of the laminated substrate.

2. The filler-application apparatus according to claim 1, wherein the protector is a plate with an opening that allows a bevel portion of the laminated substrate, which is rotated by the substrate holder, to pass through.

3. The filler-application apparatus according to claim 2, wherein the plate has an upper surface that is located between a tip and an end of the bevel portion of the laminated substrate when viewed in a radial direction of the laminated substrate.

4. The filler-application apparatus according to claim 3, wherein an edge of the opening in the plate is made of a material that allows contact with the laminated substrate, or is coated with that material.

5. The filler-application apparatus according to claim 2, wherein the plate is made of a material that can adsorb the filler, or is coated with that material.

6. The filler-application apparatus according to claim 1, wherein the protector has a suction nozzle that is arranged in proximity to a collision area of the laminated substrate with the filler.

7. The filler-application apparatus according to claim 1, wherein the protector is a dome configured to cover a collision area of the laminated substrate with the filler, and
the dome has a through-hole that allows the filler, which has been injected from the application device, to pass through.

8. The filler-application apparatus according to claim 2, wherein the protector further has a dome configured to cover a part of the laminated substrate protruding from the opening in the plate, and
the dome has a through-hole that allows the filler, which has been injected from the application device, to pass through.

9. The filler-application apparatus according to claim 7 er 8, wherein the dome is made of a material that can adsorb the filler, or is coated with that material.

10. The filler-application apparatus according to claim 7, wherein the dome has a plurality of suction holes extending from an inner surface to an outer surface of the dome,
the protector includes a dome-suction mechanism configured to suction an internal space of the dome through the plurality of suction holes from an outer side of the dome, and
the dome-suction mechanism includes at least one suction nozzle arranged in proximity to an outer surface of the dome.

11. The filler-application apparatus according to claim 7, wherein the dome has a plurality of non-penetrating holes formed in an inner surface of the dome.

12. The filler-application apparatus according to claim 1, wherein the application device is a dispenser configured to inject the filler as intermittent droplets into the gap in the laminated substrate.
